(19) United States
(12) Patent Application Publication
(10) Pub. No.: US 2004/0152330 A1
(43) Pub. Date: Aug. 5, 2004

(54) Tunneling barrier for a copper damascene via

(75) Inventors: Jick M. Yu, San Jose, CA (US); Ling Chen, Sunnyvale, CA (US)

Correspondence Address: Applied Materials, Inc., Patent/ Legal Dept., M/S 2061, P.O. Box 450A, Santa Clara, CA, 95052, US

(73) Assignee: APPLIED MATERIALS, INC.

(21) Appl. No.: 10/700,325

(22) Filed: Nov. 3, 2003

Related U.S. Application Data
(60) Provisional application No. 60/423,610, filed on Nov. 4, 2002.

(51) Int. Cl. H01L 21/302; H01L 21/461

(52) U.S. Cl. 438/716

(57) ABSTRACT

A process of forming a via through a inter-level dielectric layer and the product. The via is formed by etching a via hole through the inter-level dielectric layer in an area overlying a conductive feature, such a lower copper metallization. Atomic layer deposition (ALD) forms a very thin refractory metal nitride barrier layer over the sidewalls and bottom of the via. Its thickness is less than 1.5 nm, and may be formed with no more than six ALD cycle. A copper seed layer is sputtered onto the barrier including the bottom portion, and copper is electrochemically filled into the hole. The barrier is thin enough to have a low electrical resistance, as may be explained by electronic quantum mechanical tunneling. Further, the crystallography and defects of the underlying copper continue across the thin barrier into the overlying copper.

### RELATED APPLICATION

This application claims benefit of provisional application Serial No. 60/423,610, filed Nov. 4, 2002.

### FIELD OF THE INVENTION

The invention relates generally to barrier layers in vias formed in integrated circuits. In particular, the invention relates to barrier layers formed by chemical vapor deposition.

### BACKGROUND ART

Most semiconductor integrated circuits include several levels of interconnects, also called metallization levels, to electrically interconnect the millions to hundreds of millions of transistors found in advanced integrated circuits. Each metallization level includes a dielectric layer, typically based upon silicon oxide although other, low-k dielectric materials are being pursued. Via holes are etched into the dielectric layer separating two metallization levels. A metallization material is filled into the via holes to form the vertical interconnects, and the metallization material is further patterned on the top of the dielectric layer to form the horizontal interconnects.

In the recent past, aluminum has been the metallization material of choice. However, copper metallization is becoming increasingly prevalent because of its low resistivity, its reduced electromigration, and the ease of depositing copper with electroplating.

For both aluminum and copper metallization, it has been recognized that the via hole needs to be lined with a thin barrier layer to prevent the diffusion of the metal atoms of the metallization into the dielectric and the diffusion of the oxygen atoms of the dielectric into the metallization, both of which may be deleterious. The barrier layer may also act as a glue layer adhering the metal to the dielectric layer to nucleate growth of the metal. A simple copper via structure is schematically illustrated in cross-section in FIG. 1 just prior to the chemical mechanical polishing (CMP) step. A lower dielectric layer 10 has a conductive feature 12 formed in or on top of its upper surface. For vias interconnecting two metallization layers, the conductive feature 12 is the copper metallization of the lower layer, composed of either substantially pure copper or an alloy of materials with copper to an alloying percentage of less than 10 wt %. Examples of copper alloying materials include magnesium and aluminum. On the other hand, a contact interconnects the first-level metallization with the underlying silicon substrate. In the case of a contact, the conductive feature 12 is associated with a silicon transistor and may be monocrystalline silicon, typically doped, be silicided silicon, or be a polysilicon gate or conductive line. Forming a contact is more demanding because of the potential of degrading the semiconductor material. Only vias will hereafter be referred to, but it is understood that a contact is very similar and many of the advantages of the invention may be applied to contacts, which will be included in the definition of a via unless specifically stated to the contrary.

A second-level dielectric layer 14 is deposited over both the lower-level dielectric layer 10 and the conductive feature 12. A via hole 16 is etched through the area of the upper dielectric layer 14 overlying the conductive feature 12. A barrier layer 18 is conformally coated onto the etched upper dielectric layer 14 and includes a field portion 20 on top of the dielectric layer 14, a sidewall portion 22 on the vertically extending sidewalls of the via hole 16, and a bottom portion 24 at the bottom of the via 24 over the conductive feature 12. A thin copper seed layer 26 is deposited on the top of the barrier layer 22 to both serve as the electroplating electrode and to seed the growth of the electroplated copper. Electrochemical plating (ECP) fills a via metallization 28 into the lined via hole 16 and over the top of the dielectric layer 14. Alternatively sputtering or chemical vapor deposition may be used to fill the via hole 16. The copper compositions for both the seed and ECP copper may be those compositions listed above for the copper conductive feature 12. Although not illustrated, the structure is then subjected to chemical mechanical polishing (CMP) to remove the portion of the copper outside of the via hole 16 and on top of the dielectric layer 14. The copper remaining in the via hole 16 forms an electrical connection through the upper dielectric layer 14 to the conductive feature 12. For dual-damascene structures to be described later the same copper metallization also provides for horizontal interconnects over the upper dielectric layer 14.

For copper metallization, the typical barrier is tantalum nitride (TaN), but titanium nitride (Ti/TiN) may instead be used, and tungsten nitride (WN) has also been proposed. Sometimes the refractory nitride does not stick well to oxide, and a glue layer of the corresponding refractory metal is first deposited. For example, the barrier structure consists of a Ta/TaN bilayer. Of course, more complicated barrier layers based on metal nitrides are possible.

The choice of the barrier material in the typical configuration of FIG. 1 presents countervailing considerations. The various refractory metals, such as Ti, Ta, and W, are of themselves generally unsatisfactory diffusion barriers. The refractory metal nitrides such as TiN, TaN, and WN are adequate diffusion barriers even though their somewhat high electrical resistivities create a problem with the bottom portion 24 of the barrier layer 18 since this portion 24 is interposed in the electrical path between the via metallization 26 and the conductive feature 12. It is understood that the listed nitride compositions include a wide window of relative compositions around the indicated unitary stoichiometry. The resistivities of TiN and WN are somewhat less than 500μΩ-cm while that for TaN grown by chemical vapor deposition (CVD) including atomic layer deposition (ALD) is somewhat greater than 1000 μΩ-cm. The resistivity of TaN grown by physical vapor deposition (PVD) varies from 200 μΩ-cm upwards depending upon the deposition conditions. The barrier layer contributes a substantial portion of the contact resistance between the two metallization layers. On the basis of contact resistance, a high resistance barrier increases the contact resistance, counter to what is desired for a copper via.

Various suggestions have been made to remove the barrier layer deposited at the bottom of the via hole by some sort of directional etching. The etching can be performed in a separate etch chamber or by initially operating the sputter reactor depositing the copper seed layer in a different mode in which the bottom barrier rather than the target is sputtered. Alternatively, the barrier sputter reactor may be operated in a mode in which the barrier material is deposited on the sides of the via hole but not its bottom. A separate etch reactor of course increases the cost of production. When the sputter reactors are operated in wafer sputter mode, whatever material is sputtered from the via bottom is likely to redeposit on the via sidewalls. Sometimes, this presents a contamination issue. In any case, redeposition on the via sidewall further reduces the via cross section and hence increases the resistance of the copper via that fills the remainder of the hole. Further, a decrease of the minimum feature sizes to 0.10 μm and below while the thickness of inter-level dielectric remains around 1 μm results in the aspect ratios of via holes increasing to 10 and beyond. It becomes increasingly difficult to achieve the degree of processing anisotropy necessary to preferentially etch or sputter the bottom of a such high aspect-ratio holes.

Atomic layer deposition (ALD) of barrier materials has been proposed to deal with the need to tightly control barrier thickness in very narrow via holes. ALD is a chemical vapor deposition (CVD) process in which the compound barrier material is deposited one monolayer at a time. Chen et al. disclose ALD of TaN in Ser. No. 09/792,737, filed Feb. 23, 2001, incorporated herein by reference in its entirety. However, Chen et al. are more concerned with removing the thin barrier at the bottom of the via, and they consider that a barrier has a preferred minimum thickness of 0.5 nm.

### SUMMARY OF THE INVENTION

A metal nitride barrier layer may be used to coat the bottom and sides of via holes extending through a dielectric layer. Typical coating processes such as sputtering and chemical vapor deposition coat not only the dielectric sidewall but also an underlying conductive feature to be contacted by the via. According to the invention, the metal nitride barrier layer may be formed to very small thickness by atomic layer deposition involving chemical vapor deposition having parts of a deposition cycle favoring alternatively the metal and the nitrogen. The thickness may be as small as two or three cycles and be less than 1.5 nm or less than 1.0 nm. When copper is deposited over the thin barrier layer, the conductivity through the barrier layer to an underlying conductive feature, such as a lower copper layer or a silicon region associated with a transistor, is satisfactorily high.

Copper crystallography and its defects propagate across the thin barrier layer.

### BRIEF DESCRIPTION OF THE DRAWINGS

FIG. 1 is a cross-sectional view of a inter-level via.

FIG. 2 is a plot of via resistance as a function of barrier thickness.

FIG. 3 is an schematic illustration of the spatial dependence of electronic energy for an unbiased metal-insulator-metal structure.

FIG. 4 is a schematic illustration similar to FIG. 3 but for a biased structure.

FIG. 5 is a schematic illustration of electronic wave function across a metal-insulator-metal structure.

### DETAILED DESCRIPTION OF THE PREFERRED EMBODIMENTS

The technology of barrier layers was developed for aluminum metallization extending in vias through inter-level dielectric layers of silicon dioxide (silica). Aluminum is known to quickly diffuse in silica and to greatly increase its electrical conductivity. Furthermore, the aluminum is usually deposited in a relatively hot sputtering step or at least require a thermally activated reflow to fill narrow via holes. The elevated temperature greatly increases the diffusion rate. Hence, a relatively thick barrier layer, typically of TiN, is believed necessary to prevent the aluminum diffusion through the barrier. Furthermore, sputtering of any material into high aspect-ratio holes results in uncertain sidewall uniformity. As a result, thicker barriers have been preferred to assure that an effective barrier covers all portions of the via sidewall.

Many of these assumptions need to reevaluated in view of the switch to copper metallization and the availability of different types of sputter reactors.

Copper atoms are much larger than aluminum ones and more weakly bond with oxygen. The aluminum and copper atomic radii are about 0.128 μm and 0.143 nm respectively, and their ionic radii differ even more. As a result, copper diffuses much more slowly in silica than does aluminum. Furthermore, electroplating of copper is performed essentially at room temperature. The copper seed layer is relatively thin, and plasma sputter reactors have been developed that operate at very low pressure, sometimes zero pressure for copper, and thus allow the wafer to be maintained at relatively low temperatures. Accordingly, we believe that a thinner barrier, even if made of a conventional barrier material such as TaN or TiN, may be adequate.

The lack of an effective diffusion barrier is usually manifested in poor device performance and degradation over time, often resulting in failure as the diffused metal shorts the dielectric. We have however observed that reducing the thickness of a TaN barrier in a copper via to 0.5 nm does not markedly degrade the reliability of the via structure. However, atomic layer deposition (ALD) should be used to deposit very thin layers to prevent the formation of pin holes and thin spots. A thickness of 0.5 nm corresponds to about 2 atomic layers, that is, two complete ALD cycles. Thus, a thickness of less than 1.0 nm means no more than three atomic layers have been deposited. Different forms of ALD are available. Chen et al. in the above cited patent application have disclosed one type of ALD involving chemical vapor deposition (CVD) at an operating temperature of between 120 and 300° C. The reaction is a surface reaction, and the sequential process alternately emphasizing the two precursors of the two components minimizes any gas-phase reaction since the precursors of the two components, here tantalum and nitrogen, are not present in the gas phase at any one time. The nitrogen precursor may be nitrogen gas (N₂) or ammonia (NH₃), and the tantalum precursor may be pentakis (ethylmethylamino) tantalum (PEMAT).

Further, we have found that the contact resistance of thin TaN barriers between two copper layers does not linearly decrease with decreasing barrier thickness as would be expected for a resistive material following Ohms law. It instead exhibits a logarithmic behavior shown by the data and plot of FIG. 2, in which the TaN barrier thickness is plotted along the horizontal axis, and the measured via resistance RVIA minus the calculated copper resistance R_{Cu} in the via. For a 0.18 μm-wide and 1 μm-deep via, the via copper resistance R_{Cu} is about 0.5 Ω. As a result, at a TaN barrier thickness of 1.5 nm, the barrier resistance is no more than that of the copper via. For barrier thickness of 1.0 nm or less, the barrier resistance is negligible.

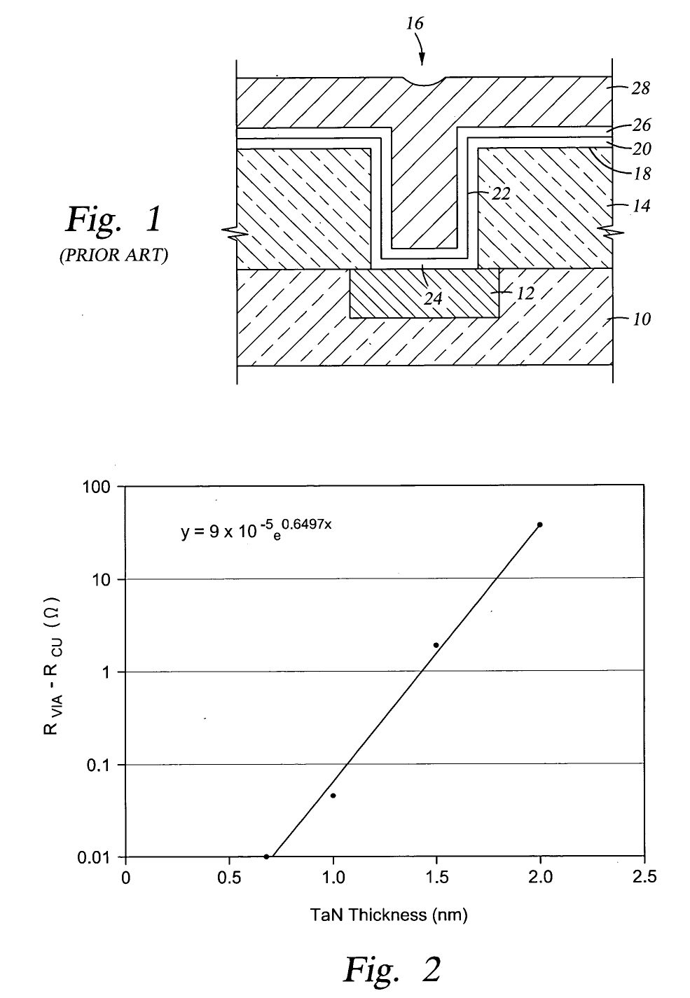

In view of the very small barrier resistance, it becomes possible even with highly resistive barrier materials to leave the bottom barrier 24 in place, as illustrated in FIG. 1, as long as the barrier layer 24 is very thin, for example, no more than 1.5 μm and preferably no more than 1.0 nm and even more preferably less than 1.0 nm. This is not an exact limit, and a more operationally quantifiable limitation is that the barrier thickness when grown by ALD is no more than four ALD monolayers, preferably no more than three monolayers. Two monolayers offer even more negligible barrier resistance, but the long-term effect on reliability may be a problem. One monolayer is possible although the barrier is then dominated by edge effects.

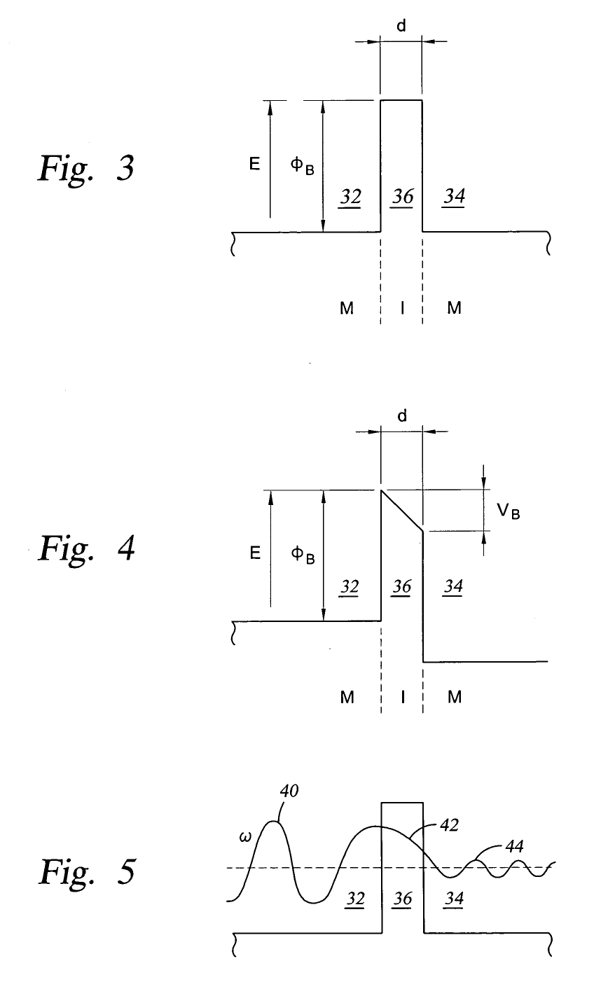

The logarithmic behavior (alternatively called exponential dependence) can be explained in terms of electronic tunneling, a quantum mechanical effect that becomes apparent only with very thin barriers of different sort. A spatial electronic band structure for the barrier is illustrated in FIG. 3 in which two metal regions 32, 34 of the same metal are separated by an insulating barrier 36 of thickness d. In this metal/insulator/metal (MIM) structure, the metal regions 32, 34 are composed of copper, and the insulating barrier 36 of TaN. The energies of the two metal regions 32 34 are the metal Fermi levels, below which there is a nearly infinite sea of free electrons. TaN in this model is considered as a perfect electrical insulator for which there is no free electron. The electronic energy level of the insulating barrier 36 is the energy required to remove an electron from the insulator, for example, by the photoelectric effect. The removed electron thus becomes a free electron in space. A similar energy for the metal layers 32, 34 is the work function, which is the energy to remove a electron from the metal, for example again, by the photoelectric effect. The energy bands line up with equal work functions, such that a barrier height φ_{B} is created between the metal layers 32, 34 and the barrier layer 36. Electron barrier heights between metals and insulators are typical in the neighborhood of 1V. The unit should properly be electron volt (eV), but the contstant multiplicative factor is not material here. If a voltage V_{B} is applied across barrier layer 36, the energy diagram is modified as illustrated in FIG. 4. This diagram does not attempt to account for the negative electron charge.

In classical physics, an electron could travel between metal regions 32, 34 only if the electron were somehow given sufficient energy to surmount the barrier 36. For an electron originating from the biased or unbiased left metal region 32, the required energy would be φ_{B}. The energy could be supplied thermally or by energetic photons. Otherwise, there is no conductivity through the barrier 36 even if it is biased.

However, according to quantum mechanics, the electronic wave function ψ represented in FIG. 5 by a sinusoidal function 40 in the left metal region 32 extending across the entire metal region 32 and represents a free electron that is completely mobile. The insulating barrier 36 does not support such a free electron within it. However, the free electron in the left metal region 32 is not completely confined to the metal region 32 because of the Heisenberg uncertainty principle but has an exponentially decaying tail 42 extending into the barrier 42. This tail 42 is similarly matched to another sinusoidal function 44 in the right metal region 44, which however is of lesser amplitude than the left-side sinusoidal functional 40. The three functions 40, 42, 44 represent the wave function for a single electron and can be interpreted as the spatially varying probability of the electron being at any one place. If the barrier 36 is thick enough, there is essentially zero probability of an electron on the left side having any probability of also being on the right. However, if the barrier 36 is relatively thin, for example, less than 2 nm, there is a significant probability that an electron on the left may appear on the right, that is, tunnel through the barrier 36.

The tunneling probability for the unbiased condition is given approximately by

Tₜ=exp(−αφ_{B}^{1/2}d).

The relationship is more complex for the biased condition but nonetheless similar. If φ_{B} is expressed in volts, and d is expressed in nanometers, then a has a value of about 10. As stated before, φ_{B} typically has a value for metal/insulator/metal structures of around 1V. Even for a 1 nm barrier the tunneling probability is low, but to give an estimate of the tunneling current the individual probability needs to be multiplied by the free electron density in copper, which is well above 10²¹ cm⁻³.

For an unbiased barrier, there is no net effect since an equal number of electrons tunnel in each direction. However, in a biased barrier, an electron is much more likely to tunnel from the high-voltage side to the low-voltage side because of the differing effective barrier heights.

The data of FIG. 2 shows an exponential dependence of 9×10⁻⁵ exp(6.497 d(nm)). Assuming that the above equation is approximately correct, αφ_{B}^{1/2} d=6.497. If α is approximately equal to 10, the φ_{B} is about 0.42V, which is in the expected range. That is, the measured contact resistances are consistent with tunneling across an insulating TaN barrier. Another set of data for a differently processed TaN barrier shows an exponential dependence of 9.9×10⁻³ exp(2.86 d(nm)), which produces a barrier height φ_{B} of about 0.08V.

Copper like most metals typically form in crystallites of various sizes and crystallographic orientations. The crystallite size in copper thin films is strongly dependent upon deposition conditions, and the crystallography affects the electrical conductivity, the wetting to layers of different materials, such as the nitride barrier, and failure mechanisms. It is typically difficult to control the copper crystallography at the contact area at the bottom of the via.

We have observed that when a nitride barrier layer, for example, 1.5 nm or less (approximately six ALD monolayers or less) of TaN, are ALD deposited on a relatively bulk copper substrate feature, the copper sputtered onto the nitride barrier has the same crystallography as the underlying copper. That is, the very thin nitride barrier layer allows epitaxial growth of microcrystalline copper across the nitride barrier. This structure is present at the bottom of the via hole 16 of FIG. 1, in which a very thin barrier layer 24 separates the underlying copper feature 12 from the copper seed layer 22 and the electroplated copper 28. Since copper is typically formed of microcrystallites, the microcrystallites of the base copper and the copper grown over the ALD barrier are similarly aligned. Even when defects propagate in copper, such as twins, the copper defect propagates across the nitride barrier. Such propagating defects are considered advantageous in that they show that no unstable surface interface is formed and they lock the after grown copper to the underlying copper. Both the copper crystallography and the copper defects are easily observed by electron microscopy.

Thus it is seen that very thin barrier layers, particularly those enabled by ALD growth, provide superior characteristics.

1. A copper metalllization structure, comprising:
a via hole extending through a dielectric layer over an underlying copper feature;
a metal nitride barrier layer formed on sides of said via hole including a bottom side thereof; and
a copper layer formed over the barrier layer at said bottom side of said via hole;
wherein a crystallography of said copper feature is aligned with a crystallography of said copper layer across said barrier layer at said bottom side of said via hole.

2. The structure of claim 1, wherein defects of said copper feature are aligned with defects of said copper layer across said barrier layer at said bottom side of said via hole.

3. The structure of claim 1, wherein said copper layer comprises a copper seed layer overlaid with electroplated copper.

4. The structure of claim 1, wherein said nitride barrier layer formed on said bottom side of said via hole is no more than 1.5 nm in thickness.

5. A copper metallization structure, comprising:
a via hole extending through a dielectric layer over an underlying conductive feature;
a metal nitride barrier layer formed on sides of said via hole including a bottom side thereof, wherein a thickness of said barrier layer at said bottom side of said via hole is no more than 1.5 nm; and
a copper layer formed over the barrier layer at said bottom side of said via hole.

6. The structure of claim 5, wherein said thickness is less than 1.0 nm.

7. The structure of claim 5, wherein said thickness corresponds to no more than three cycles of atomic layer deposition of said metal nitride barrier layer.

8 The structure of claim 5, wherein said copper layer comprises a copper seed layer overlaid with electroplated copper.

9. A method of forming a via structure in a dielectric layer having a via hole formed therethrough overlying a conductive feature beneath said dielectric layer, comprising the steps of:
depositing a metal nitride barrier layer in said via hole by no more than six cycles of atomic layer deposition; and
depositing a copper seed layer over said barrier layer on sides and a bottom of said via hole.

10. The method of claim 9, wherein said no more than six cycles consists of no more than three cycles.

11. The method of claim 9, further comprising electroplating copper over said copper seed layer in said via hole.

12. The method of claim 9, wherein said step of depositing a copper seed layer comprises sputtering.

13. A method of forming a via structure in a dielectric layer having a via hole formed therethrough overlying a conductive feature beneath said dielectric layer, comprising the steps of:
depositing by chemical vapor deposition a nitride barrier layer in said via hole and having a thickness at a bottom of said via hole of no more than 1.5 nm; and
forming a copper seed layer over said barrier layer on sides and said bottom of said via hole.

14. The method of claim 13, wherein said nitride barrier layer comprises a nitride selected from the group consisting of titanium nitride, tantalum nitride, and tungsten nitride.

15. The method of claim 13, wherein said chemical vapor deposition comprises no more than six cycles of atomic layer deposition.

16. The method of claim 15, wherein said no more than six cycles consists of no more than three cycles.

17. The method of claim 16, wherein said no more than three cycles consists of no more than two cycles.

18. The method of claim 13, wherein said thickness is no more than 1.0 nm.

19. The method of claim 18, wherein said thickness is less than 1.0 nm.

20. The method of claim 13, further comprising electroplating copper over said copper seed layer in said via hole.
